(19) United States
(12) Patent Application Publication
(10) Pub. No.: US 2009/0097220 A1
(43) Pub. Date: Apr. 16, 2009

(54) Printed circuit board

(75) Inventors: Young-Mi Lee, Daejeon (KR); Suk-Chang Hong, Cheongju-si (KR); Yong-Bin Lee, Cheongju-si (KR); Chin-Kwan Kim, Daejeon (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/010,749

(22) Filed: Jan. 29, 2008

(30) Foreign Application Priority Data
Oct. 16, 2007 (KR) 10-2007-0103915

(51) Int. Cl. H05K 1/02

(52) U.S. Cl. 361/774

(57) ABSTRACT

A printed circuit board is disclosed. The printed circuit board, which has at least one pad on which a solder ball is to be placed, includes a solder resist that covers a surface of the printed circuit board, an opening part that exposes the pad and supports the solder ball, and an extended portion formed in a perimeter of the opening part that allows an underfill to flow in between the printed circuit board and the solder ball. With this printed circuit board, the underfill can be filled in more readily between the printed circuit board and the solder balls, when mounting a component on the printed circuit board.

### CROSS-REFERENCE TO RELATED APPLICATIONS

This application claims the benefit of Korean Patent Application No. 10-2007-0103915 filed with the Korean Intellectual Property Office on Oct. 16, 2007, the disclosure of which is incorporated herein by reference in its entirety.

### BACKGROUND

1. Technical Field

The present invention relates to a printed circuit board.

2. Description of the Related Art

A “solder” is the fusible material used in brazing, or soldering, while the term “resist” is used in the manufacturing processes for printed circuit boards to describe “a protective layer that protects against a treatment or reaction.”

Therefore, a solder resist can refer to “a protective layer that covers the circuit pattern of a printed circuit board to prevent undesired contact that may occur due to the solder when mounting a component.” The solder resist may thus serve both as a protective material that protects the circuit patterns on the printed circuit board and as an insulation material between circuits.

Because the circuit pattern of a printed circuit board is made by etching a copper foil overlaid on a board, it is in principle similar to a naked line that does not have an insulation coating. As such, when mounting a component on the printed circuit board, the surface of the printed circuit board can be exposed to molten solder, which may create an undesired contact (i.e. a solder bridge). This can lead to major defects, which may not allow the electronic device to operate properly.

To prevent such defects, a protective layer is covered on the portions other than around the lands, which are needed for the soldering of the component, and this protective layer is referred to as the solder resist. Because of its function of covering, the solder resist is also known as a “solder mask.”

When mounting a component on a printed circuit board using solder balls, an underfill is injected between the component and the printed circuit board, and afterwards cured. This may prevent the solder balls from oxidation after the electrical connection is established, and may help maintain a stable electrical connection between the component and the printed circuit board.

FIG. 1 is a plan view illustrating a printed circuit board according to the related art, FIG. 2 is a cross-sectional view illustrating a printed circuit board according to the related art, and FIG. 3 is a cross-sectional view illustrating a printed circuit board and solder balls according to the related art.

As illustrated in FIG. 1, a circular shape is used for the opening 2 of the solder resist 4 in a currently used printed circuit board. In cases where the opening 2 of the solder resist 4 is formed in a circular shape, a curb may be formed between the pad 6 and the solder resist 4, as illustrated in FIG. 2. The boundary of the circular opening 2 may support the perimeter of the circular solder ball 10, whereby a space may be formed that is enclosed by the solder resist 4 between the insulation layer 12 and pad 6 and the solder ball 10, in which the underfill cannot be filled, as illustrated in FIG. 3.

If there is a space formed between the solder ball 10 and the printed circuit board in which the underfill cannot be filled, not only the physical adhesion of the solder ball 10 but also the electrical reliability of the printed circuit board may be adversely affected.

### SUMMARY

An aspect of the invention is to provide a printed circuit board, in which the occurrence of voids, due to the underfill material not being filled in, can be prevented, when mounting a component.

One aspect of the invention provides a printed circuit board having at least one pad on which a solder ball is to be placed. The printed circuit board includes a solder resist which covers a surface of the printed circuit board, an opening part which exposes the pad and supports the solder ball, and an extended portion formed in a perimeter of the opening part that allows an underfill to flow in between the printed circuit board and the solder ball.

Here, the opening part can expose the pad and a portion of the printed circuit board adjacent to the pad, and can support the solder ball by point contact.

The extended portion can be formed on one side of the opening part and can be formed on two or more sides of the opening part.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a plan view illustrating a printed circuit board according to the related art.

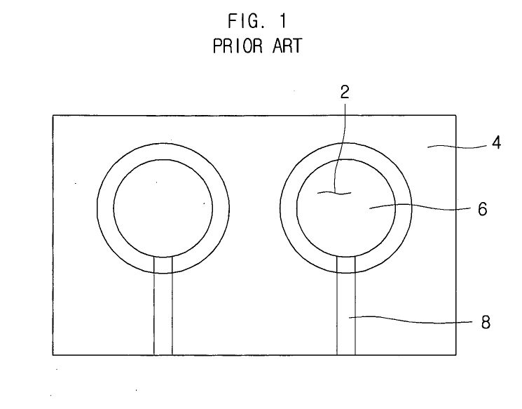

FIG. 2 is a cross-sectional view illustrating a printed circuit board according to the related art.

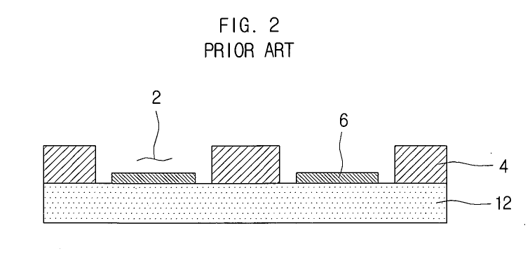

FIG. 3 is a cross-sectional view illustrating a printed circuit board and solder balls according to the related art.

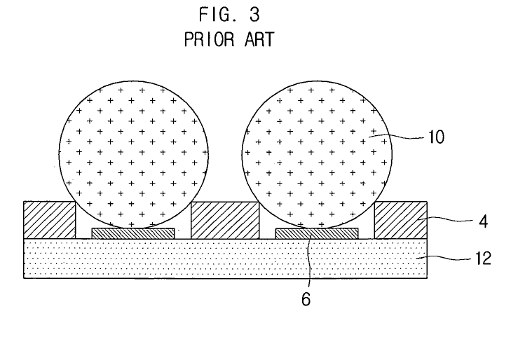

FIG. 4 is a plan view illustrating a printed circuit board according to an embodiment of the invention.

FIG. 5 is a cross-sectional view illustrating a printed circuit board and solder balls according to an embodiment of the invention.

FIG. 6 is a perspective view illustrating a printed circuit board according to an embodiment of the invention.

FIG. 7 is a plan view illustrating a printed circuit board according to another embodiment of the invention.

FIG. 8 is a perspective view illustrating a printed circuit board according to another embodiment of the invention.

FIG. 9 is a plan view illustrating a printed circuit board according to yet another embodiment of the invention.

FIG. 10 is a perspective view illustrating a printed circuit board according to yet another embodiment of the invention.

### DETAILED DESCRIPTION

The printed circuit board according to certain embodiments of the invention will be described below in more detail with reference to the accompanying drawings, in which those elements are rendered the same reference numeral that are the same or are in correspondence, regardless of the figure number, and redundant explanations are omitted.

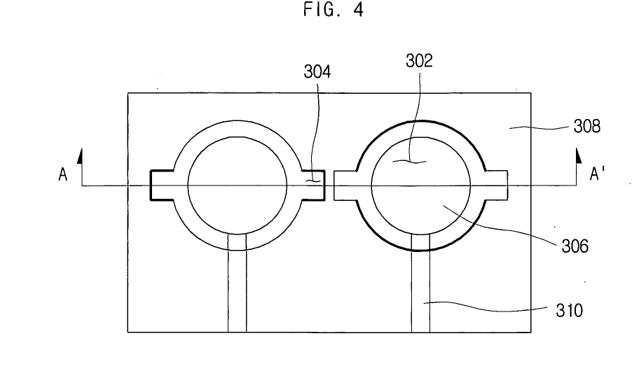

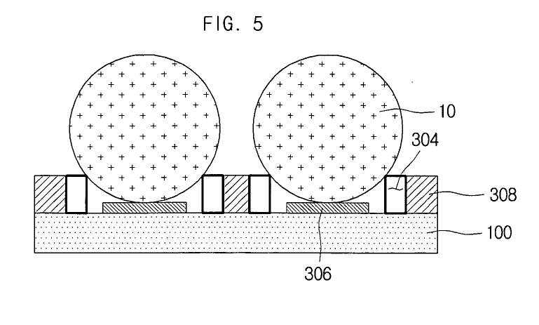

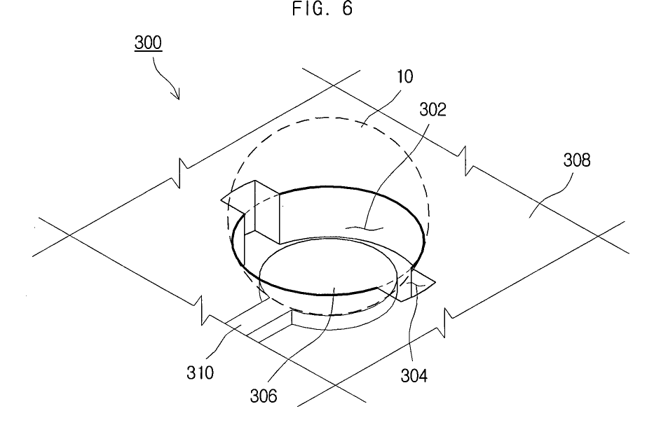

FIG. 4 is a plan view illustrating a printed circuit board according to an embodiment of the invention, FIG. 5 is a cross-sectional view illustrating a printed circuit board and solder balls according to an embodiment of the invention, and FIG. 6 is a perspective view illustrating a printed circuit board according to an embodiment of the invention. In FIGS. 4 to 6 are illustrated solder balls 10, an insulation layer 100, a printed circuit board 300, opening boundaries 302, extended portions 304, pads 306, a solder resist 308, and a circuit pattern 310.

The printed circuit board 300 according to an embodiment of the invention may include a solder resist 308, which covers a surface of the printed circuit board 300, opening boundaries 302, which expose pads 306 and support solder balls, and extended portions 304, which are formed on the perimeters of the opening boundaries 302 and through which the underfill flows in that will be filled in between the printed circuit board 300 and the solder balls 10. This printed circuit board 300 can make it easier to fill in the underfill between the printed circuit board 300 and the solder balls 10.

The printed circuit board 300 can be composed mainly of an insulation layer 100 and a circuit pattern 310. The circuit pattern 310 may be formed on a surface of the insulation layer 100. The pads 306 may cover portions of the circuit pattern 310 to provide electrical and physical connections to a component mounted on the printed circuit board 300. The pads 306 may be solder ball pad, on which solder balls 10 may be placed. A solder ball pad can be formed by forming a Ni/Au plating layer on the circuit pattern 310, or by an OSP (organic solderability preservative) treatment. The solder resist 308 may be a heat-resistant covering material that protects particular areas from solder during the soldering process.

As illustrated in FIG. 4, the solder resist 308 may cover a surface of the printed circuit board 300. The solder resist 308 can cover portions of the insulation layer 100 and the circuit pattern 310 of the printed circuit board 300. The opening boundaries 302 and the extended portions 304 can be formed in the solder resist 308.

The opening part 302 can be formed in the solder resist 308, and can expose a pad 306 and a portion of the printed circuit board 300 adjacent to the pad 306, while supporting the solder ball 10 placed on the pad 306. As illustrated in FIG. 4, the opening part 302 can be formed in a circular shape that exposes the pad 306 and a portion of the printed circuit board 300 adjacent to the pad 306. As illustrated in FIGS. 5 and 6, when a solder ball 10 is placed, the perimeter of the opening part 302 can be in contact with the solder ball 10 and may support the solder ball 10.

The extended portion 304 can be formed at the perimeter of the opening part 302, to permit the inflow of underfill that will be filled in between printed circuit board 300 and the solder ball 10. The extended portion 304 may be a space formed at the perimeter of the opening part 302, i.e. at the edge of the opening part 302, in connection with the opening part 302, and may provide a space in which the underfill may be filled between the solder ball 10 and the printed circuit board 300. As illustrated in FIG. 4, the extended portion 304 can be formed on either side of an opening part 302.

As illustrated in FIGS. 5 and 6, the extended portions 304 may be portions that extend from the perimeter of an opening part 302, which are not put into contact with the solder ball 10 when the solder ball 10 is mounted, and which can provide spaces in which the underfill may be filled. The underfill may flow in between the printed circuit board 300 and the solder ball 10 through the extended portions 304, to prevent the occurrence of voids. In this particular embodiment, the extended portions 304 can be formed on both sides of the perimeter of an opening part 302, to ensure sufficient space for the inflow of underfill.

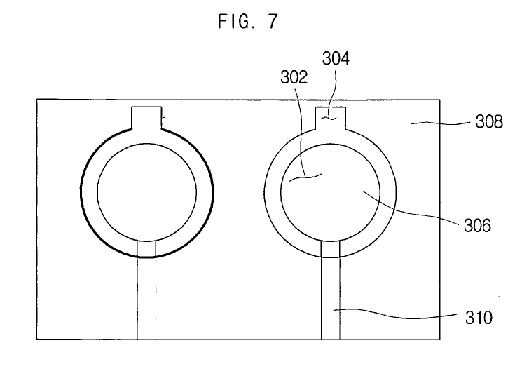

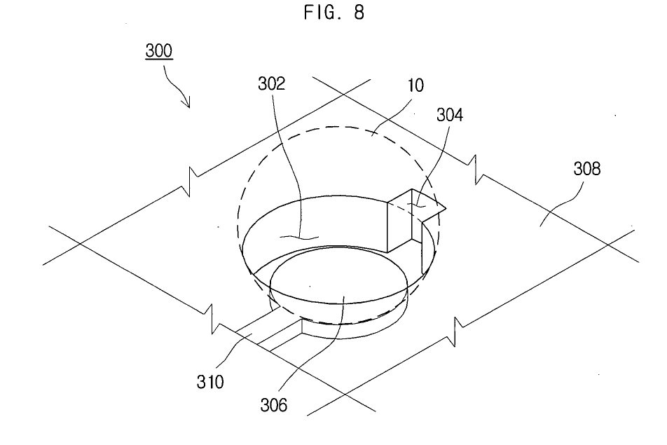

FIG. 7 is a plan view illustrating a printed circuit board 300 according to another embodiment of the invention, and FIG. 8 is a perspective view illustrating a printed circuit board 300 according to another embodiment of the invention.

The extended portions 304 in the printed circuit board 300 according to this particular embodiment can each be formed on one side of an opening part 302, to facilitate the inflow of underfill between the solder balls 10 and the printed circuit board 300. As illustrated in FIG. 7, the extended portion 304 may be formed at one side of the perimeter of the opening part 302. In addition, it can be formed to match the direction of the circuit pattern 310. When the extended portions 304 are formed to match the direction of the circuit pattern 310, the extended portions 304 may be formed without having to increase the pitch between the lines of the circuit pattern 310. As illustrated in FIG. 8, forming the extended portion 304 in one side of the opening part 302 may increase the portions where the opening part 302 supports the solder ball 10.

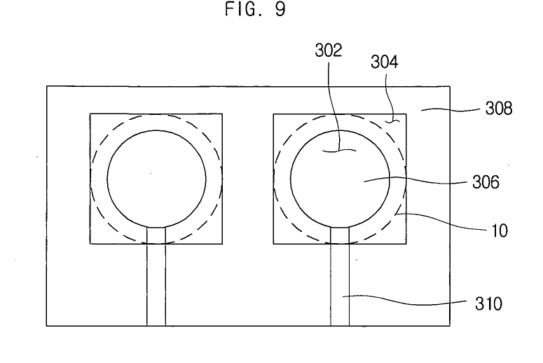

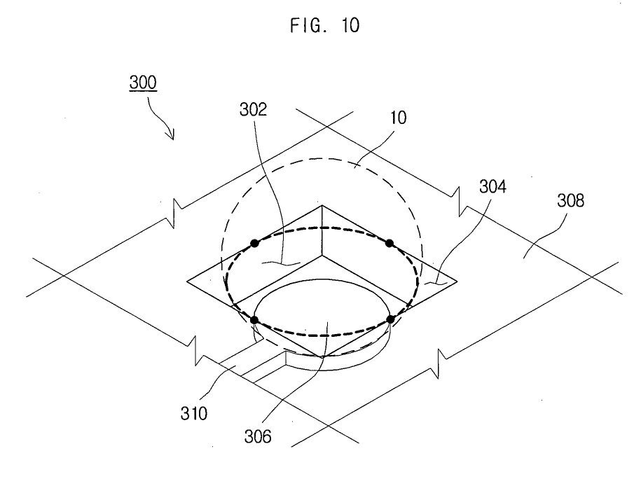

FIG. 9 is a plan view illustrating a printed circuit board 300 according to yet another embodiment of the invention, and FIG. 10 is a perspective view illustrating a printed circuit board 300 according to yet another embodiment of the invention.

The opening parts 302 of the printed circuit board 300 according to this embodiment can support the solder balls 10 while maintaining point contact with the solder balls 10. As illustrated in FIG. 9, the opening part 302, which exposes the pad 306 and portions of the printed circuit board 300 adjacent to the pad 306 and supports the solder ball 10, can be in the form of the circular area defined by the dotted lines. As illustrated in FIG. 10, the circular opening part 302 defined by the thick dotted line may expose the pad 306 and the printed circuit board 300 adjacent to the pad 306, and may support a solder ball 10 while in point contact with the solder ball 10.

Of course, the solder ball may not be shaped as an ideal sphere, due to the effects of temperature, etc., and may be in line contact with the opening part 302, instead of point contact. In such cases, the opening part 302 may still support the solder balls 10 and may be defined as a shape that is not circular. As such, point contact in this context refers not only to the case where the solder ball 10 is an ideal sphere, such that the opening part 302 supports the solder ball 10 by perfect point contact, but also to cases where the shape of the solder ball 10 is substantially close to a sphere, such that the opening part 302 supports the solder ball 10 by line contact.

As illustrated in FIG. 9, in this embodiment, the extended portions 304 can be the spaces formed along the perimeter of the circularly defined opening part 302 in which the underfill material can be filled, and can be formed in four positions along the perimeter of the opening part 302. By increasing the extended portions 304, the inflow of the underfill can further be facilitated.

As set forth above, by using certain embodiments of the invention, the underfill can be filled in more readily between the printed circuit board and the solder balls, when mounting a component on the printed circuit board.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A printed circuit board having at least one pad configured to have a solder ball placed thereon, the printed circuit board comprising:
a solder resist covering a surface of the printed circuit board;
an opening part exposing the pad and supporting the solder ball; and
an extended portion formed in a perimeter of the opening part and enabling an underfill to flow in between the printed circuit board and the solder ball.

2. The printed circuit board of claim 1, wherein the opening part exposes the pad and a portion of the printed circuit board adjacent to the pad.

3. The printed circuit board of claim 1, wherein the opening part supports the solder ball by point contact.

4. The printed circuit board of claim 1, wherein the extended portion is formed on one side of the opening part.

5. The printed circuit board of claim 1, wherein the extended portion is formed on two sides of the opening part.
